(19) United States
(12) Patent Application Publication
(10) Pub. No.: US 2025/0359488 A1
(43) Pub. Date: Nov. 20, 2025

(54) FABRICATION OF SUPERCONDUCTING TUNNEL JUNCTIONS

(71) Applicant: International Business Machines Corporation, Armonk, NY (US)

(72) Inventors: Marco Turchetti, White Plains, NY (US); Santino Carnevale, Stamford, CT (US)

(21) Appl. No.: 18/606,484

(22) Filed: Mar. 15, 2024

(51) Int. Cl. H10N 60/01; H10N 60/12

(52) U.S. Cl. CPC H10N 60/0912; H10N 60/12

(57) ABSTRACT

A method is provided to form a superconducting tunnel junction device. An undercut trench is formed in a substrate surface. A first superconducting metal layer is formed on the substrate surface such that the undercut trench causes a discontinuity in the first superconducting metal layer. An insulating layer is formed on the first superconducting metal layer, and a second superconducting metal layer is formed on the insulating layer. The second superconducting metal layer, the insulating layer, and the first superconducting metal layer are patterned to form a superconducting tunnel junction device on the substrate adjacent to the undercut trench, which comprises first and second electrodes, and a barrier layer disposed therebetween. The first electrode comprises a portion of the first superconducting metal layer at the discontinuity thereof, the barrier layer comprises a portion of the insulating layer, and the second electrode comprises a portion of the second superconducting metal layer.

### BACKGROUND

This disclosure generally relates to techniques for fabricating superconducting quantum devices and, in particular, techniques for fabricating superconducting tunnel junction devices (e.g., Josephson junction devices). A quantum computing system is implemented using superconducting circuits and devices that utilize superconducting quantum bits (qubits) for generating and processing quantum information. In general, superconducting qubits are electronic circuits which behave as quantum mechanical anharmonic (non-linear) oscillators with quantized states, when cooled to cryogenic temperatures. A quantum computing system integrates various superconducting components such as capacitors, inductors, resonators, Josephson junctions, and interconnects to fabricate superconducting qubits and other superconducting circuitry and devices. Each of these superconducting components can introduce non-idealities which affect the overall performance of a quantum processor comprising qubits, as well as the characteristics of individual qubits, which are extremely sensitive.

In a conventional fabrication process, superconducting components such as capacitors, inductors, resonators, and interconnects are deposited and patterned together using well-established large-scale manufacturing processes (e.g., Complementary Metal-Oxide-Semiconductor (CMOS) fabrication). On the other hand, superconducting tunnel junction devices (e.g., Josephson junctions) are fabricated separately using ad-hoc, unconventional processing techniques such as ion milling, double-angle shadow evaporation over a Dolan Bridge, lift-off patterning, etc., which implement separate deposition steps to fabricate superconducting tunnel junction devices. Such techniques are not ideal for various reasons. For example, double-angle shadow evaporation techniques are not compatible for large-scale manufacturing of superconducting tunnel junction devices (e.g., Josephson junctions). Moreover, such techniques introduce non-idealities and high process variability that can lead to significant variation and non-uniformities in the sizes of the tunnel junction devices (e.g., different overlap areas) over a large wafer area, which can negatively affect quantum system performance.

### SUMMARY

Embodiments of the disclosure include techniques for fabricating superconducting tunnel junction devices, such as Josephson junctions.

An exemplary embodiment includes a method which comprises: forming an undercut trench in a surface of a substrate; forming a first superconducting metal layer on the surface of the substrate such that the undercut trench causes a discontinuity in the first superconducting metal layer; forming an insulating layer on the first superconducting metal layer; forming a second superconducting metal layer on the insulating layer; and patterning the second superconducting metal layer, the insulating layer, and the first superconducting metal layer to form at least one superconducting tunnel junction device in an area of the substrate adjacent to the undercut trench. The at least one superconducting tunnel junction device comprises a first electrode, a second electrode, and a barrier layer disposed between the first electrode and the second electrode, the first electrode comprising a portion of the first superconducting metal layer at the discontinuity thereof, the barrier layer comprising a portion of the insulating layer, and the second electrode comprising a portion of the second superconducting metal layer.

Another exemplary embodiment includes a method which comprises: forming an undercut trench in a surface of a substrate; forming a first superconducting metal layer on the surface of the substrate such that the undercut trench causes a discontinuity in the first superconducting metal layer; forming an insulating layer on the first superconducting metal layer; forming a second superconducting metal layer on the insulating layer; and patterning the second superconducting metal layer, the insulating layer, and the first superconducting metal layer to form a superconducting quantum bit. The superconducting quantum bit comprises a first capacitor pad, a second capacitor pad, and at least one Josephson junction disposed between and connected to the first capacitor pad and the second capacitor pad. The at least one Josephson junction comprises a first electrode, a second electrode, and a barrier layer disposed between the first electrode and the second electrode, the first electrode comprising a portion of the first superconducting metal layer at the discontinuity thereof, the barrier layer comprising a portion of the insulating layer, and the second electrode comprising a portion of the second superconducting metal layer.

Another exemplary embodiment includes a device which comprises a substrate comprising at least one undercut trench formed in a surface thereof, and at least one superconducting tunnel junction device disposed on the substrate adjacent to an opening of the undercut trench. The at least one superconducting tunnel junction device comprises a first electrode, a second electrode, and a barrier layer disposed between the first electrode and the second electrode. The first electrode is disposed adjacent to the opening of the undercut trench. A first portion of the second electrode is disposed over an upper surface of the first electrode, and a second portion of the second electrode is disposed adjacent to a sidewall surface of the first electrode and extends to the opening of the undercut trench.

Other embodiments of the disclosure will be described in the following detailed description of embodiments, which is to be read in conjunction with the accompanying figures.

### BRIEF DESCRIPTION OF THE DRAWINGS

FIGS. 1A and 2B schematically illustrate a quantum device comprising a superconducting tunnel junction device, according to an exemplary embodiment of the disclosure.

FIGS. 2A-12B schematically illustrate a process for fabricating a quantum device comprising a superconducting tunnel junction device, according to an exemplary embodiment of the disclosure, wherein:

FIGS. 2A and 2B schematically illustrate the quantum device at an intermediate stage of fabrication in which a first etch mask is formed on a surface of a substrate;

FIGS. 3A and 3B schematically illustrate the quantum device at an intermediate stage of fabrication after etching the substrate using the first etch mask to form a trench in the surface of the substrate;

FIGS. 4A and 4B schematically illustrate the quantum device at an intermediate stage of fabrication after removing the etch mask from the surface of the substrate;

FIGS. 5A and 5B schematically illustrate the quantum device at an intermediate stage of fabrication after forming a first metal layer on the surface of the substrate;

FIGS. 6A and 6B schematically illustrate the quantum device at an intermediate stage of fabrication after forming an insulating layer on the first metal layer;

FIGS. 7A and 7B schematically illustrate the quantum device at an intermediate stage of fabrication after forming a second metal layer over the insulating layer;

FIGS. 8A and 8B schematically illustrate the quantum device at an intermediate stage of fabrication after forming a second etch mask on the second metal layer;

FIGS. 9A and 9B schematically illustrate the quantum device at an intermediate stage of fabrication after utilizing the second etch mask to pattern the second metal layer;

FIGS. 10A and 10B schematically illustrate the quantum device at an intermediate stage of fabrication after forming a third etch mask to further pattern the second metal layer and the insulating layer;

FIGS. 11A and 11B schematically illustrate the quantum device at an intermediate stage of fabrication after utilizing the third etch mask to pattern the second metal layer and the insulating layer, and removing a remaining portion of the third etch mask; and

FIGS. 12A and 12B schematically illustrate the quantum device at an intermediate stage of fabrication after forming a fourth etch mask which is utilized to etch the first metal layer to further define and isolate device components.

FIG. 13 schematically illustrates a superconducting quantum bit having a Josephson junction which can be constructed using a fabrication method according to an exemplary embodiment of the disclosure.

FIG. 14 schematically illustrates a frequency-tunable superconducting quantum bit having Josephson junctions which can be constructed using a fabrication method according to an exemplary embodiment of the disclosure.

FIGS. 15A and 15B schematically illustrate a quantum device comprising serially connected superconducting tunnel junction devices, according to another exemplary embodiment of the disclosure.

FIGS. 16A and 16B schematically illustrate a quantum device comprising serially connected superconducting tunnel junction devices, according to another exemplary embodiment of the disclosure.

### DETAILED DESCRIPTION

Embodiments of the disclosure will now be discussed in further detail with regard to techniques for fabricating superconducting tunnel junction devices, such as Josephson junctions, wherein such techniques enable nanofabrication of, e.g., Josephson Junctions using methods that are compatible with large-scale manufacturing, and enable fabrication of Josephson Junctions using the same process modules utilized to fabricate other superconducting components such as capacitors, inductors, resonators, interconnects, etc. For example, as explained in further detail below, overlapping electrodes of superconducting tunnel junction devices (e.g., Josephson junctions) are fabricated using the same metal deposition steps for fabricating other superconducting components such as capacitors, inductors, resonators, interconnects, etc. on a given quantum chip. The exemplary fabrication techniques as disclosed herein do not require the use of separate metal deposition steps for fabricating superconducting tunnel junction devices, and do not rely on unconventional processing techniques such as double-angle shadow evaporation. In this regard, the exemplary fabrication techniques for superconducting tunnel junction devices as disclosed herein are compatible with large-scale manufacturing of quantum chips, and enable fabrication of Josephson Junctions with improved reliability and manufacturability for quantum processors.

It is to be understood that the various layers, structures, and regions shown in the accompanying drawings are schematic illustrations that are not drawn to scale. In addition, for case of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, or structures, and thus, a detailed explanation of the same or similar features, elements, or structures will not be repeated for each of the drawings. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount. The term “exemplary” as used herein means “serving as an example, instance, or illustration”. Any embodiment or design described herein as “exemplary” is not to be construed as preferred or advantageous over other embodiments or designs. The word “over” as used herein to describe forming a feature (e.g., a layer) “over” a side or surface, means that the feature (e.g., the layer) may be formed “directly on” (i.e., in direct contact with) the implied side or surface, or that the feature (e.g., the layer) may be formed “indirectly on” the implied side or surface with one or more additional layers disposed between the feature (e.g., the layer) and the implied side or surface.

In addition, the term “quantum chip” or “chip” as used herein refers to a die (e.g., semiconductor die) which comprises a superconducting electronic integrated circuit comprising various superconducting components such as qubits, tunable couplers, ground planes, signal coplanar waveguides, and resonators, etc. A plurality of dies having the same and/or different configurations of superconducting electronic integrated circuits, can be fabricated on a wafer (e.g., semiconductor wafer), wherein the individual dies can be diced (cut) from the wafer using a die singulation process to provide singulated dies which can be packaged to construct quantum processors. The terms “quantum chip” and “chip” and “die” are synonymous terms and used interchangeably herein.

To provide spatial context to the different structural orientations of the semiconductor structures shown in the drawings, XYZ Cartesian coordinates are shown in the drawings. The terms “vertical” or “vertical direction” or “vertical height” as used herein denote a Z-direction of the Cartesian coordinates shown in the drawings, and the terms “horizontal,” “horizontal direction,” “lateral,” or “lateral direction” as used herein denote an X-direction and/or a Y-direction of the Cartesian coordinates shown in the drawings.

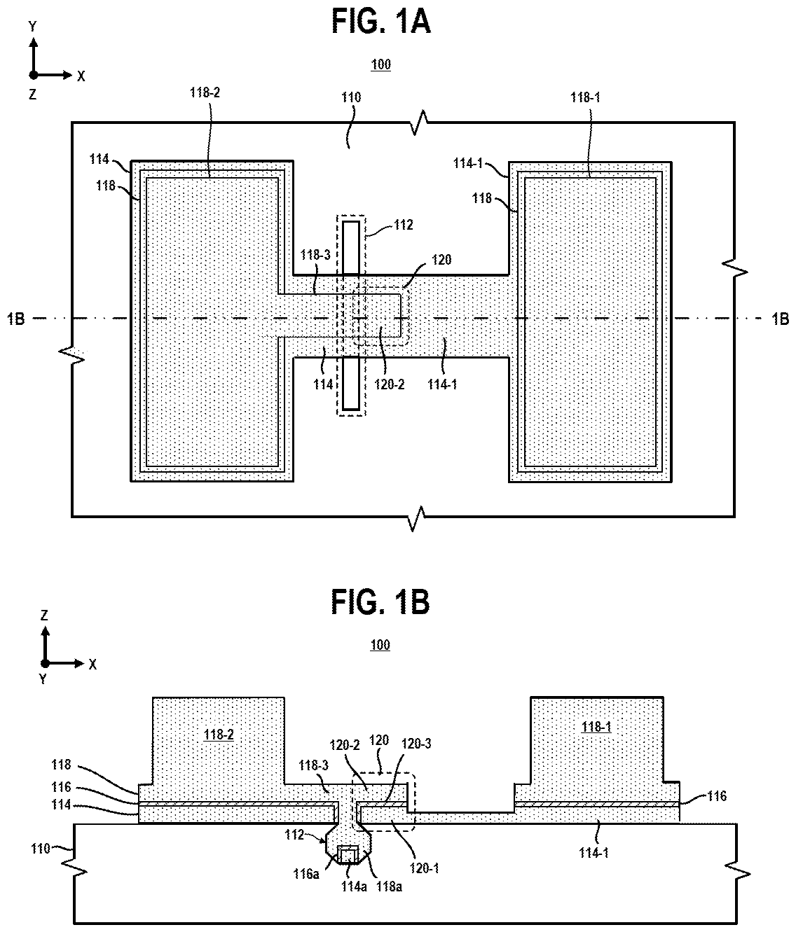

FIGS. 1A and 1B schematically illustrates a quantum device 100 comprising a superconducting tunnel junction device, according to an exemplary embodiment of the disclosure, wherein FIG. 1A is a schematic top plan view of the quantum device 100, and FIG. 1B is a schematic cross-sectional side view of the quantum device 100 along line 1B-1B in FIG. 1A. As schematically shown in FIGS. 1A and 1B, the quantum device 100 (e.g., quantum chip) comprises a substrate 110, a trench 112 that is formed in a surface of the substrate 110, a first metal layer 114, an insulating layer 116, a second metal layer 118, and a superconducting tunnel junction device 120 (e.g., Josephson junction). The superconducting tunnel junction device 120 comprises a first electrode 120-1, a second electrode 120-2, and an insulating layer 120-3 (or barrier layer 120-3) disposed between the first and second electrodes 120-1 and 120-2. The first and second metal layers 114 and 118 are formed of a superconducting metal/metallic material. As explained in further detail below, the insulating layer 116 is patterned to form the barrier layer 120-3 of the superconducting tunnel junction device 120.

Furthermore, as schematically illustrated in FIGS. 1A and 1B, the second metal layer 118 is patterned to form, e.g., a first metallic structure 118-1, a second metallic structure 118-2, and a third metallic structure 118-3, wherein at least a portion of the third metallic structure 118-3 comprises the second electrode 120-2 of the superconducting tunnel junction device 120. The first metal layer 114 is patterned to form, e.g., a metallic interconnect structure 114-1 which is electrically coupled to the first metallic structure 118-1, wherein at least a portion of the metallic interconnect structure 114-1 comprises the first electrode 120-1 of the superconducting tunnel junction device 120. As is known in the art, the primary variables that affect Josephson coupling energy of Josephson junctions are the overlap area between the first and second electrodes 120-1 and 120-2, and the thickness of the barrier layer 120-3 therebetween.

The trench 112 comprises an undercut trench which is formed in the surface of the substrate 110 prior to depositing a layer of metallic material which forms the first metal layer 114. As explained in further detail below, the trench 112 is configured to facilitate the fabrication of the superconducting tunnel junction device 120 by, e.g., allowing the metallic interconnect structure 114-1 to be isolated from the other portions of the first metal layer 114, and enabling separation of the first metal layer 114 and the second metal layer 118, in particular, separation between the first and second electrodes 120-1 and 120-2 on one side of the superconducting tunnel junction device 120. As schematically shown in FIG. 1B, the trench 112 comprises residual material (e.g., a residual metallic material 114a and a residual insulating layer 116a), which are formed within the trench 112 during the deposition of the first metal layer 114 and formation of the insulating layer 116. In addition, the trench 112 is filled with a metallic material 118a during the deposition of the second metal layer 118. As explained in further detail below, the trench 112 allows the components of the superconducting tunnel junction device 120 to be formed concurrently with the process modules that form the first and second metal layers 114 and 118 and the insulating layer 116 between the first and second metal layers 114 and 118.

It is to be noted that while FIGS. 1A and 1B show a single superconducting tunnel junction device 120 for case of illustration and discussion, the quantum device 100 can be a wafer comprising multiple dies, with each die comprising multiple superconducting tunnel junction devices, e.g., Josephson junctions, for various quantum components such as superconducting qubits, superconducting qubit couplers, superconducting quantum interference devices (SQUIDs), Josephson transmission lines (JTLs) which are used to implement components such as Josephson traveling wave parametric amplifiers (JTWPAs), and Josephson traveling wave parametric frequency converters (JTWPFCs), and other quantum components which are implemented using Josephson junctions. By way of example, in some embodiments, FIGS. 1A and 1B schematically illustrate a superconducting transmon qubit which comprises a superconducting capacitor coupled in parallel with a Josephson junction, wherein the first and second metallic structures 118-1 and 118-2 comprise first and second capacitor electrodes of a coplanar parallel plate capacitor, and the superconducting tunnel junction device 120 is a Josephson junction that is coupled to and between the first and second capacitor electrodes of the coplanar parallel plate capacitor.

It is to be noted that as a consequence of an exemplary process (as discussed below) for fabricating the quantum device 100, a parasitic superconducting tunnel junction device is formed by virtue of the portion of the insulating layer 116 disposed between overlapping portions of the metallic interconnect structure 114-1 and the first metallic structure 118-1. The parasitic superconducting tunnel junction device is relatively large in area as compared to the smaller area of the superconducting tunnel junction device 120. While the large parasitic superconducting tunnel junction device is serially connected with the smaller superconducting tunnel junction device 120 between the first and second metallic structures 118-1 and 118-2 (e.g., capacitor pads of a transmon qubit), the larger parasitic superconducting tunnel junction device is effectively an electrical short between the metallic interconnect structure 114-1 and the first metallic structure 118-1, and thus has an insignificant impact on device performance (e.g., does not affect performance of the transmon qubit).

Indeed, given the relatively smaller area of the superconducting tunnel junction device 120 as compared to the large area of the parasitic superconducting tunnel junction device, the superconducting tunnel junction device 120 comprises a much higher normal-state junction resistance Rn than that of the parasitic superconducting tunnel junction device. As a result, the superconducting current in the path between the first and second metallic structures 118-1 and 118-2 is dominated by the higher normal-state resistance of the superconducting tunnel junction device 120. In this regard, when the ratio of the area of the larger parasitic tunnel junction device to the area of the smaller superconducting tunnel junction device 120 is sufficiently large, the larger parasitic tunnel junction device will have insignificant impact on the device performance.

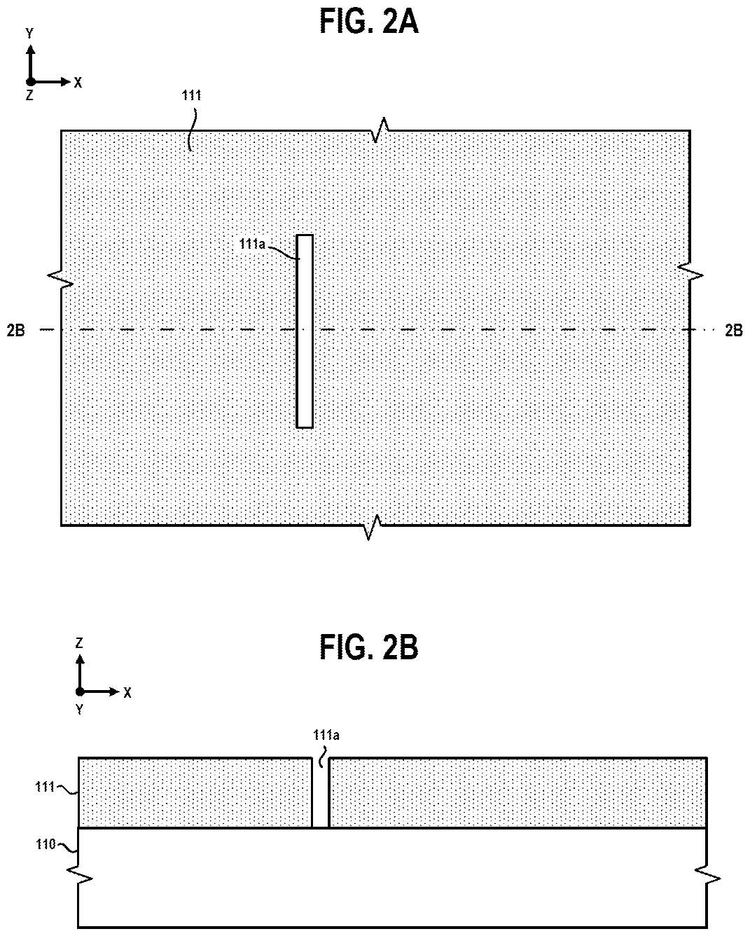

Various methods for fabricating superconducting tunnel junction devices will now be discussed in further detail with reference to FIGS. 2A-16B. In some embodiments, the exemplary fabrication methods implement CMOS fabrication techniques that enable wafer-scale manufacturing of superconducting tunnel junction devices (e.g., Josephson junctions) using the same process modules for fabricating other superconducting components such as capacitors, inductors, resonators, interconnects, etc. For example, FIGS. 2A-12B schematically illustrate a process for fabricating a quantum device comprising a superconducting tunnel junction device, according to an exemplary embodiment of the disclosure. For illustrative purposes, FIGS. 2A-12B are presented to schematically illustrate a process for fabricating the quantum device 100 of FIGS. 1A and 1B which comprises the superconducting tunnel junction device 120, although it is to be understood that the same or similar process flow and process modules are utilized to fabricate other types of quantum devices having one or more Josephson junctions.

FIGS. 2A and 2B schematically illustrate the quantum device 100 at an intermediate stage of fabrication in which a first etch mask 111 is formed on the substrate 110. FIG. 2A is a schematic top plan view of the quantum device 100, and FIG. 2B is a schematic cross-sectional side view of the quantum device 100 along line 2B-2B in FIG. 2A. In some embodiments, the substrate 110 comprises a semiconductor wafer such as a silicon wafer, or other types of wafer substrates (e.g., sapphire substrate). The first etch mask 111 comprises an opening 111a which is utilized to etch a trench in the surface of the substrate 110. The first etch mask 111 is formed using suitable techniques. For example, in some embodiments, the first etch mask 111 is formed by spin coating a layer of light-sensitive photoresist material onto the surface of the substrate 110, followed by performing a photolithography process in which a photolithographic mask is utilized to expose the portion of the photoresist layer (which corresponds to the opening 111a) to light, followed by a development process to etch away the exposed portion of the photoresist layer to form the first etch mask 111 which comprises the opening 111a.

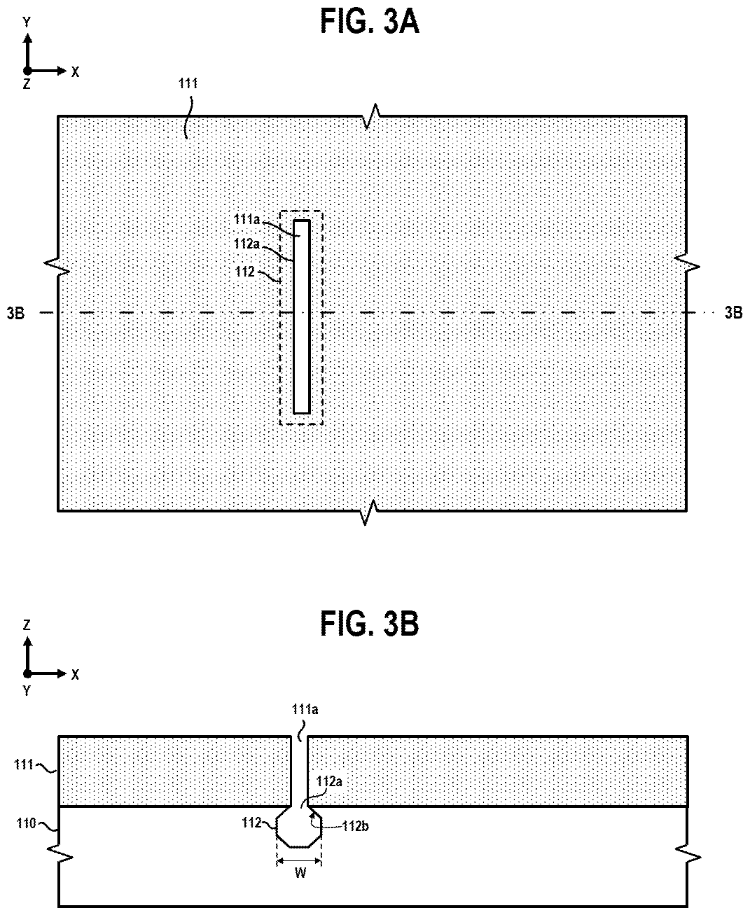

Next, FIGS. 3A and 3B schematically illustrate the quantum device 100 at an intermediate stage of fabrication in which the trench 112 is formed in the surface of the substrate 110. FIG. 3A is a schematic top plan view of the quantum device 100, and FIG. 3B is a schematic cross-sectional side view of the quantum device 100 along line 3B-3B in FIG. 3A. As shown in FIG. 3B, the trench 112 (or undercut trench 112) comprises a trench opening 112a and undercut regions 112b, wherein the undercut regions 112b define a trench width W (in the X direction) which is greater than a width of the trench opening 112a (in the X direction). As explained in further detail below, the undercut trench 112 is designed to separate and prevent shorting of the first and second electrodes of the resulting superconducting tunnel junction device 120.

The undercut trench 112 is formed using a suitable etch process which is configured to etch the exposed material of the substrate 110 selective to the photoresist material of the first etch mask 111. FIG. 3B illustrates an exemplary embodiment in which the undercut trench 112 comprises an octagon-shaped profile. However, in other embodiments, the undercut trench 112 can be formed to have other shapes (e.g., oval-shaped, sigma-shaped, etc.) which include undercut regions such that the trench opening 112a is smaller than the trench width W. In some embodiments, the undercut trench 112 is formed using a wet etch process with a suitable etchant solution, such as alkaline chemistries including KOH, NH₄OH, TMAH, or NaOH, result in the formation of sharp corners in the silicon due to a preferential etching the direction of the crystalline orientation of the substrate. In some embodiments, the undercut trench 112 is formed by a dry etch process (e.g., RIE (reactive ion etch) to form a trench with vertical sidewalls, followed by a wet etch to form the undercut regions 112b using techniques known to those of ordinary skill in the art.

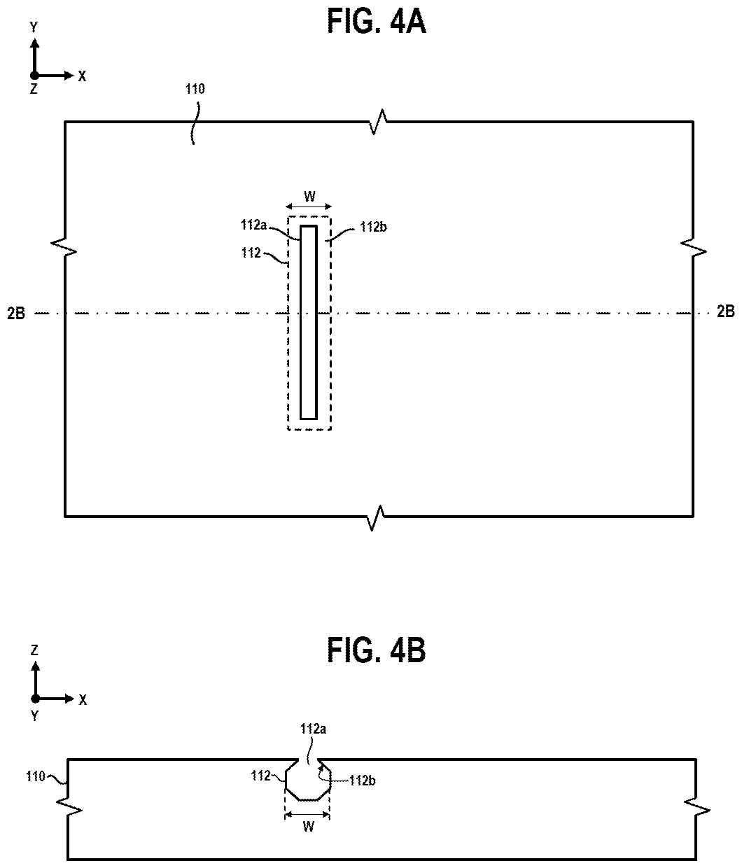

FIGS. 4A and 4B schematically illustrate the quantum device 100 at an intermediate stage of fabrication after removing the first etch mask 111 from the surface of the substrate 110. FIG. 4A is a schematic top plan view of the quantum device 100, and FIG. 4B is a schematic cross-sectional side view of the quantum device 100 along line 4B-4B in FIG. 4A. The first etch mask 111 is removed using any suitable photoresist stripping and cleaning processes, resulting in the intermediate structure shown in FIGS. 4A and 4B which comprises the substrate 110 with the undercut trench 112 formed in the upper surface thereof. As noted above, the undercut trench 112 comprises the undercut regions 112b which define a trench width W (in the X direction) which is greater than a width of the trench opening 112a (in the X direction).

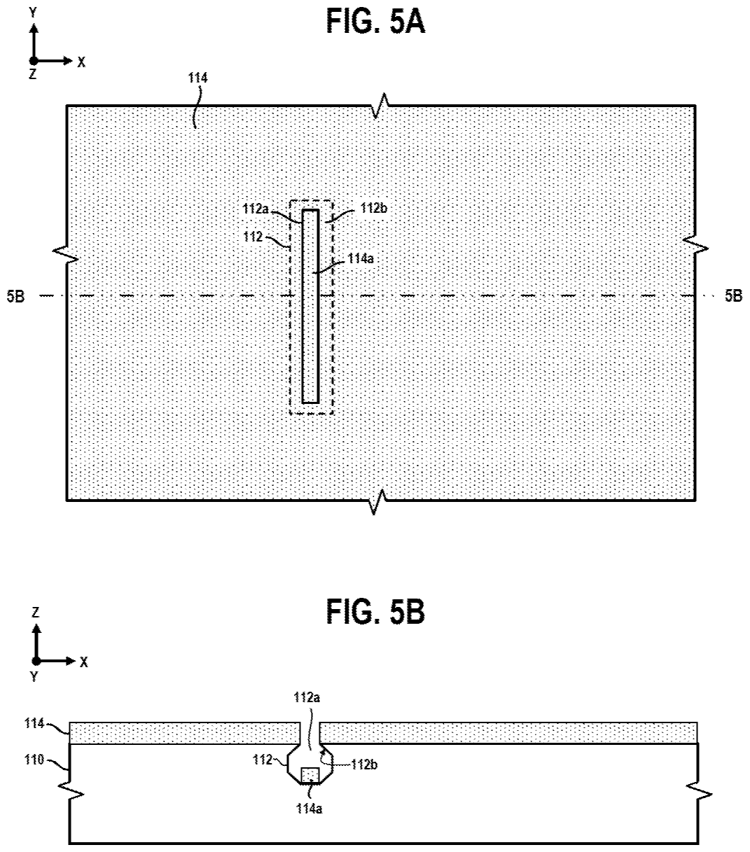

Next, FIGS. 5A and 5B schematically illustrate the quantum device 100 at an intermediate stage of fabrication after forming the first metal layer 114 on the surface of the substrate 110, wherein FIG. 5A is a schematic top plan view of the quantum device 100, and FIG. 5B is a schematic cross-sectional side view of the quantum device 100 along line 5B-5B in FIG. 5A. The first metal layer 114 may comprise any suitable superconducting metallic material such as aluminum, niobium, titanium, tungsten, molybdenum, nitrides of the same, a combination thereof, and/or the like. A superconducting metallic material is any metallic material that exhibits superconducting properties (e.g., no electrical resistance, expels magnetic fields when in a superconducting state) at or below a superconducting critical temperature. The first metal layer 114 can be formed by depositing a metallic material using any suitable deposition technique which provides directional deposition on horizontal surfaces. For example, the first metal layer 114 can be formed by physical vapor deposition (PVD) (e.g., evaporation, sputtering) or chemical vapor deposition (CVD), etc., wherein the parameters of the deposition process are configured to enable directional deposition (as opposed to a conformal deposition) of the metallic material.

As schematically illustrated in FIG. 5B, the undercut trench 112 causes a discontinuity in the first metal layer 114 at the trench opening 112a, i.e., the undercut trench 112 causes a distinct break in physical continuity of the first metal layer 114. Moreover, the directional deposition of the first metal layer 114 causes metallic material 114a to be deposited on the bottom surface of the undercut trench 112, which is exposed through the trench opening 112a, while preventing metallic material from being deposited on the sidewall surfaces of the undercut trench 112. Moreover, the undercut regions 112b of the trench 112 provide an overhang feature which prevents the metallic material from being deposited on the inner sidewalls of the trench 112 below the overhang feature of the undercut regions 112b.

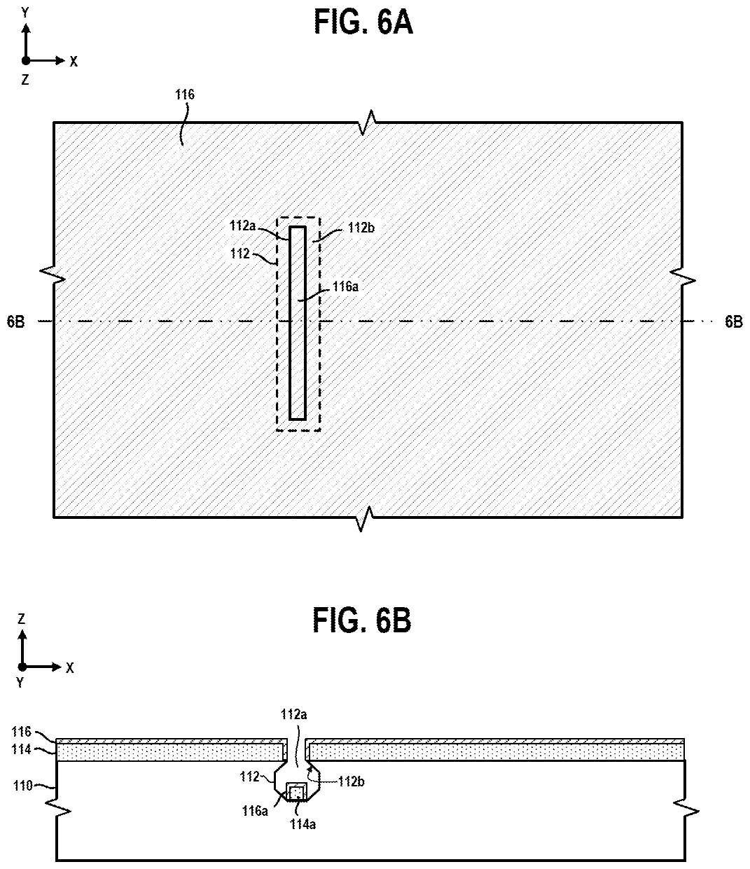

Next, FIGS. 6A and 6B schematically illustrate the quantum device 100 at an intermediate stage of fabrication after forming the insulating layer 116 on the first metal layer 114, wherein FIG. 6A is a schematic top plan view of the quantum device 100, and FIG. 6B is a schematic cross-sectional side view of the quantum device 100 along line 6B-6B in FIG. 6A. In some embodiments, the insulating layer 116 is formed by conformally depositing a layer of insulating material on exposed surfaces of the first metal layer 114. In other embodiments, the insulating layer 116 is formed by performing an oxidation process to oxidize the exposed surfaces of the first metal layer 114. For example, in some embodiments, an oxidation process is performed by exposing the surfaces of the first metal layer 114 to oxygen (O₂) at a fixed concentration and pressure for a given time, to oxidize the exposed surfaces of the first metal layer 114. In an exemplary non-limiting embodiment, the first metal layer 114 comprises aluminum and the insulating layer 116 comprises an aluminum oxide that is formed by diffusive oxidation of the surfaces of the first metal layer 114. In other embodiments, when the first metal layer 114 is formed of another type of superconducting metallic material (e.g., molybdenum, vanadium, etc.), the insulating layer 116 may be an oxide of the superconducting metallic material (e.g., molybdenum oxide, vanadium oxide, etc.).

As schematically illustrated in FIG. 6B, the insulating layer 116 is formed on vertical surfaces of the first metal layer 114 near the trench opening 112a. In addition, the residual insulating layer 116a is formed on the residual metallic material 114a on the bottom surface of the undercut trench 112. As noted above, the residual metallic material 114a and the residual insulating layer 116a in the undercut trench 112 are residual structures/artifacts that result from the fabrication process, and do not serve as functional circuit components or elements of the superconducting tunnel junction device. As explained in further detail below, the insulating layer 116 is further patterned to form a barrier layer of the superconducting tunnel junction device.

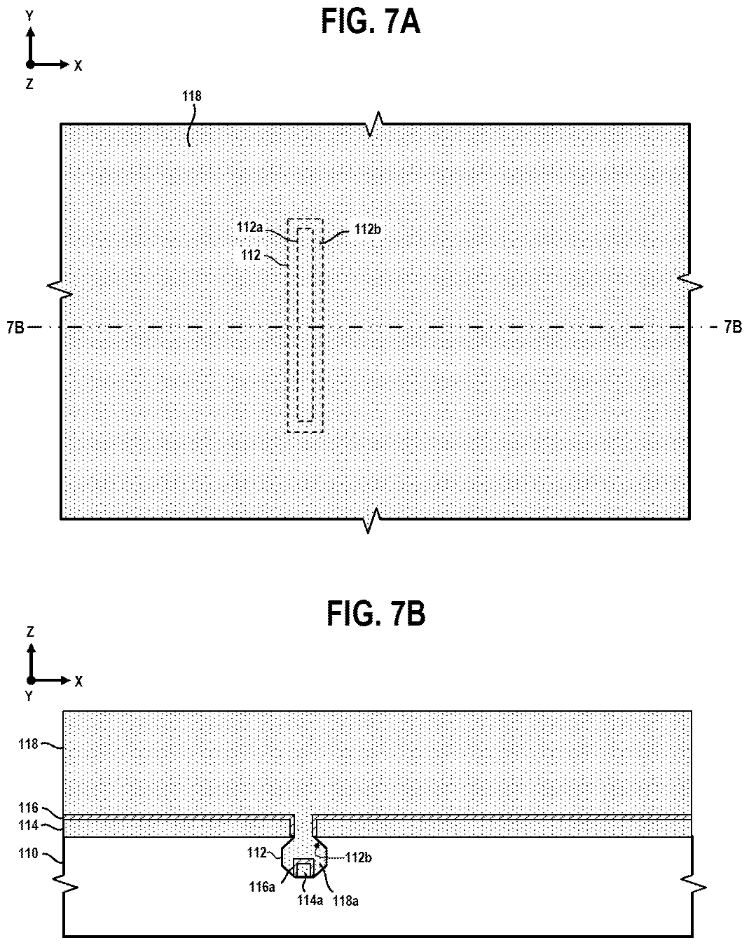

Next, FIGS. 7A and 7B schematically illustrate the quantum device 100 at an intermediate stage of fabrication after forming the second metal layer 118 over the insulating layer 116, wherein FIG. 7A is a schematic top plan view of the quantum device 100, and FIG. 7B is a schematic cross-sectional side view of the quantum device 100 along line 7B-7B in FIG. 7A. In some embodiments, the second metal layer 118 is formed of the same superconducting metallic material as the first metal layer 114 (e.g., aluminum, niobium, titanium, tungsten, molybdenum, nitrides of the same, a combination thereof, and/or the like). The second metal layer 118 is formed by depositing a metallic material using any suitable deposition technique (e.g., PVD, evaporation, etc.). As schematically illustrated in FIG. 7B, the deposition process to form the second metal layer 118 results in filling the undercut trench 112 with metallic material 118a. In particular, the trench opening 112a is filled with metallic material such that a portion of the second metal layer 118 is disposed adjacent to the portions of the insulating layer 116 on the vertical surfaces of the first metal layer 114 just above the trench opening 112a.

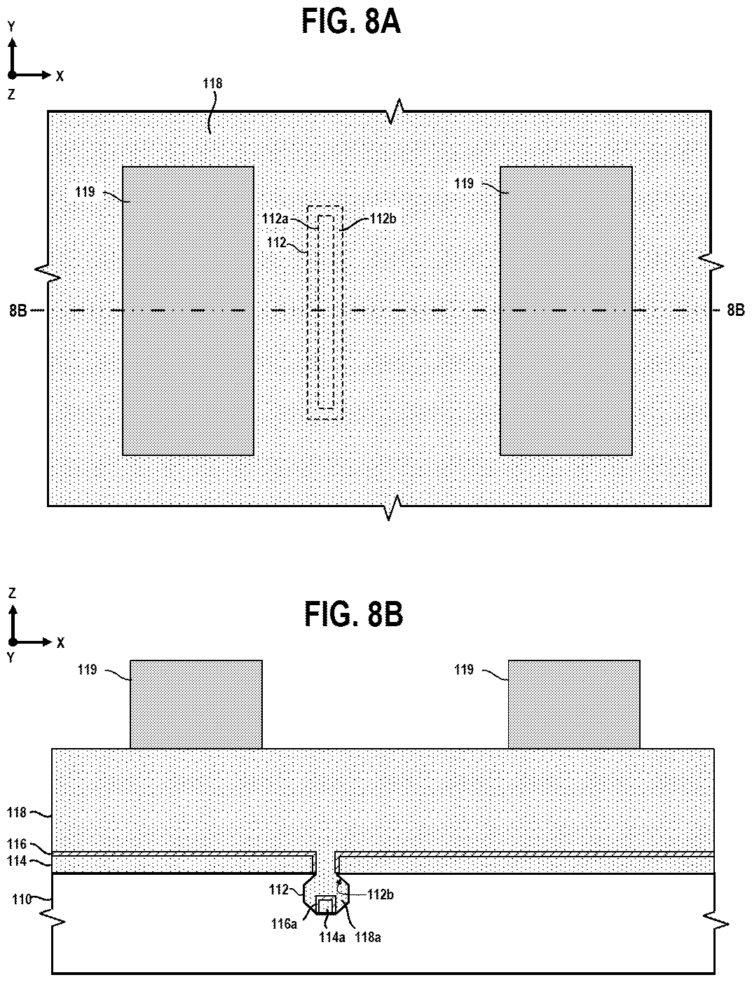

A next stage of the fabrication process involves forming an etch mask and utilizing the etch mask to pattern the second metal layer 118. For example, FIGS. 8A and 8B schematically illustrate the quantum device 100 at an intermediate stage of fabrication after forming a second etch mask 119 on the second metal layer 118, wherein FIG. 8A is a schematic top plan view of the quantum device 100, and FIG. 8B is a schematic cross-sectional side view of the quantum device 100 along line 8B-8B in FIG. 8A. In some embodiments, the second etch mask 119 is formed by spin coating a layer of photoresist material on second metal layer 118, followed by exposing and developing the layer of photoresist material using known methods to form the second etch mask 119. In an exemplary embodiment, the second etch mask 119 comprises an image of metallic structures (e.g., capacitor electrodes, interconnects, etc.) which are formed by etching the second metal layer 118.

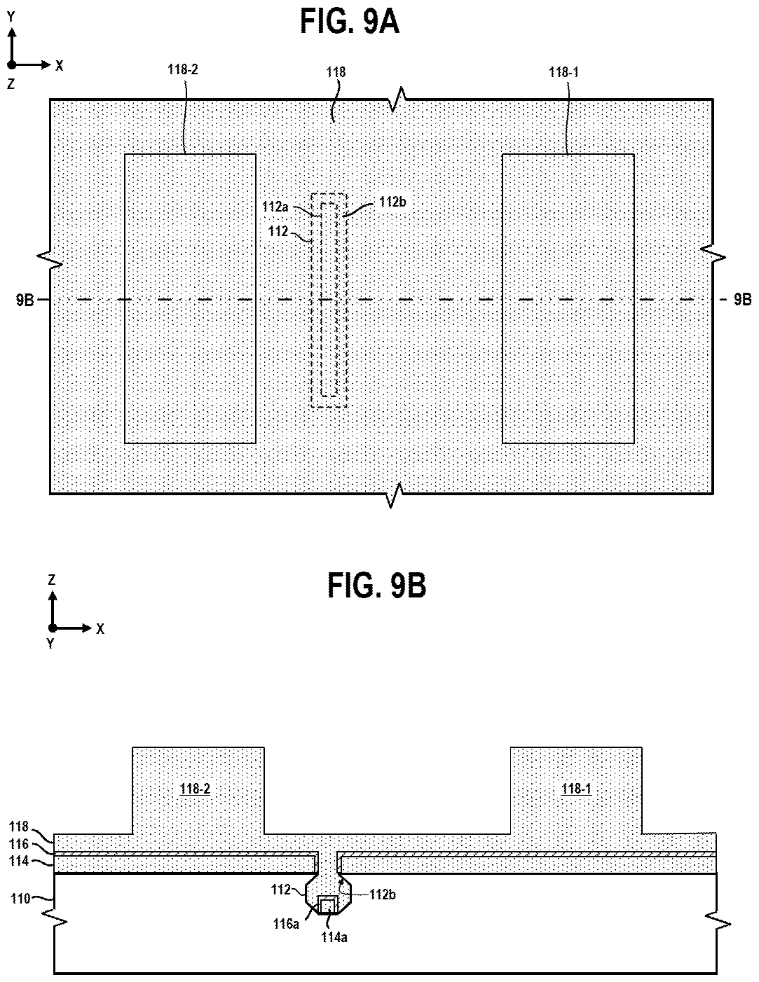

For example, FIGS. 9A and 9B schematically illustrate the quantum device 100 at an intermediate stage of fabrication after utilizing the second etch mask 119 to pattern the second metal layer 118, wherein FIG. 9A is a schematic top plan view of the quantum device 100, and FIG. 9B is a schematic cross-sectional side view of the quantum device 100 along line 9B-9B in FIG. 9A. In particular, FIGS. 9A and 9B schematically illustrate the first and second metallic structures 118-1 and 118-2 (e.g., capacitor electrodes) that are formed after etching the second metal layer 118 and stripping the second etch mask 119. In an exemplary embodiment, the second metal layer 118 is etched using a dry etch process (e.g., RIE) with an etch chemistry and etch environment that is suitable to etch the metallic material of the second metal layer 118. The etch process is performed using a timed etch to ensure that the etching of the second metal layer 118 terminates before reaching the insulating layer 116.

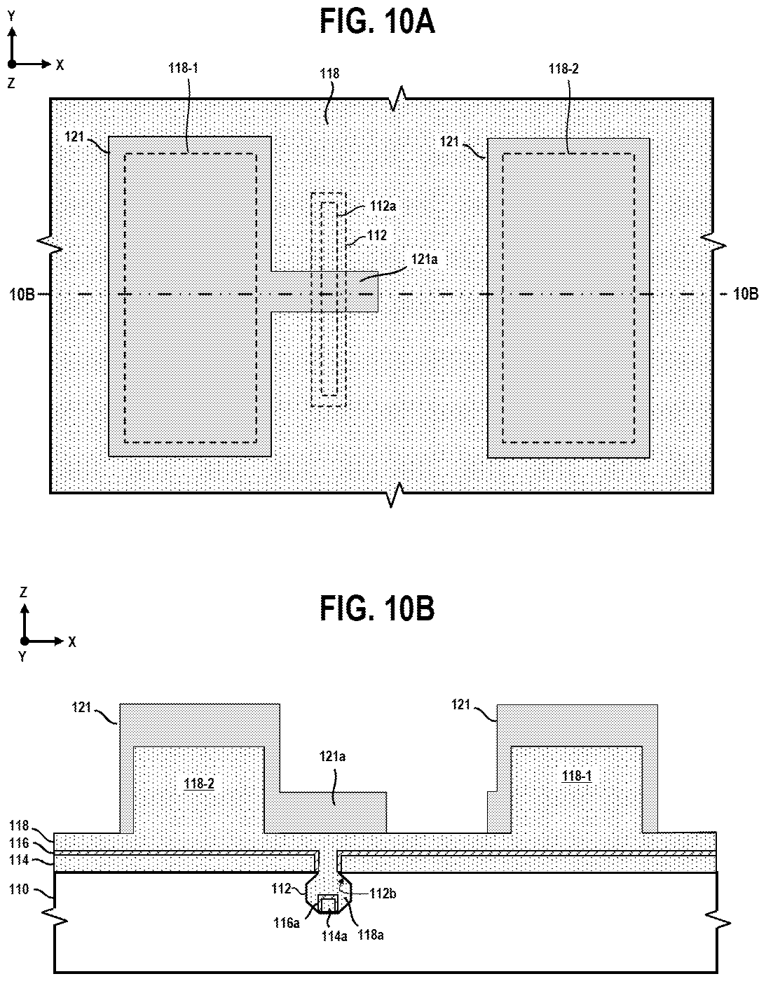

Following the formation of the first and second metallic structures 118-1 and 118-2, the fabrication process continues by performing additional etch processes to pattern the first and second metal layers 114 and 118 and the insulating layer 116 to form the superconducting tunnel junction device 120 and isolate device components. For example, FIGS. 10A and 10B schematically illustrate the quantum device 100 at an intermediate stage of fabrication after forming a third etch mask 121 to further pattern the second metal layer 118 and the insulating layer 116, wherein FIG. 10A is a schematic top plan view of the quantum device 100, and FIG. 10B is a schematic cross-sectional side view of the quantum device 100 along line 10B-10B in FIG. 10A. In some embodiments, the third etch mask 121 comprises layer of photoresist material that is deposited and patterned using photolithography. As schematically illustrated in FIGS. 10A and 10B, the third etch mask 121 is formed to cover the first and second metallic structures 118-1 and 118-2, and comprises a mask portion 121a that defines an image of the third metallic structure 118-3 (FIGS. 1A and 1B) which, in turn, defines the second electrode 120-2 of the superconducting tunnel junction device 120. As shown in FIG. 10A, the third etch mask 121 is formed to expose areas of the second metal layer 118 to be etched.

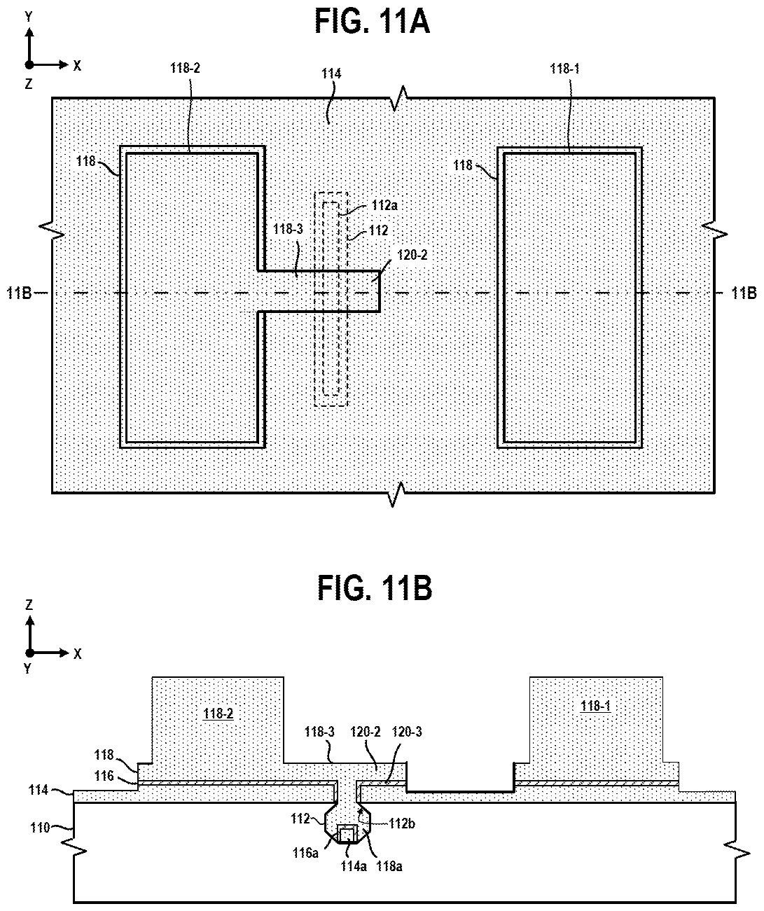

Next, FIGS. 11A and 11B schematically illustrate the quantum device 100 at an intermediate stage of fabrication after utilizing the third etch mask 121 to pattern the second metal layer 118 and the insulating layer 116, and removing the second etch mask 119, wherein FIG. 11A is a schematic top plan view of the quantum device 100, and FIG. 11B is a schematic cross-sectional side view of the quantum device 100 along line 11B-11B in FIG. 11A. In an exemplary embodiment, the second metal layer 118 and the insulating layer 116 are etched using one or more sequential dry etch process (e.g., RIE) with etch chemistries and etch environments that are suitable to etch the metallic material of the second metal layer 118 and insulating material of the insulating layer 116. The etching is performed to remove the exposed portions of the second metal layer 118 and the insulating layer 116, and terminated after reaching the first metal layer 114.

As schematically illustrated in FIGS. 11A and 11B, the etch process results in electrically isolating the first and second metallic structures 118-1 and 118-2, and defining the third metallic structure 118-3 which extends from the second metallic structure 118-2, and which comprises the second electrode 120-2 of the superconducting tunnel junction device 120. In addition, the etch process results in patterning the insulating layer 116 to define the barrier layer 120-3 of the superconducting tunnel junction device 120.

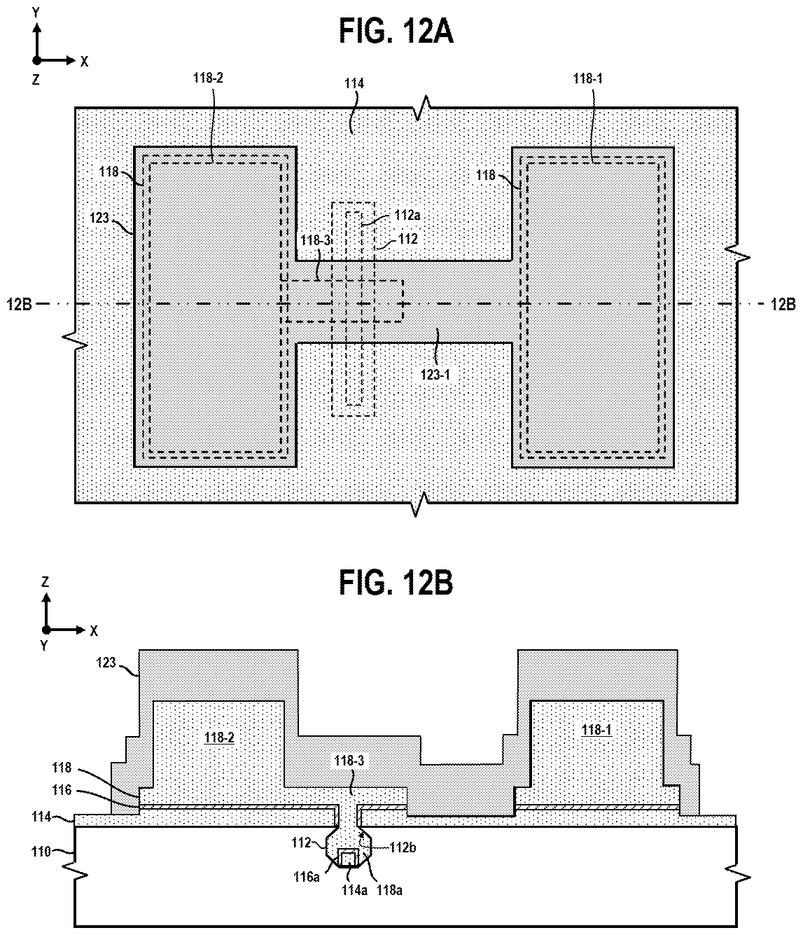

Next, another etch process is performed to pattern the first metal layer 114 to further define and isolate device components. For example, FIGS. 12A and 12B schematically illustrate the quantum device 100 at an intermediate stage of fabrication after forming a fourth etch mask 123 which is utilized to etch the first metal layer 114 to further define and isolate device components, wherein FIG. 12A is a schematic top plan view of the quantum device 100, and FIG. 12B is a schematic cross-sectional side view of the quantum device 100 along line 12B-12B in FIG. 12A. In some embodiments, the fourth etch mask 123 comprises a layer of photoresist material that is deposited and patterned using photolithography. As schematically illustrated in FIGS. 12A and 12B, the fourth etch mask 123 is formed to cover the first, second, and third metallic structures 118-1, 118-2, and 118-3. The fourth etch mask 123 comprises a mask portion 123a that covers the third metallic structure 118-3, as well as a portion of the first metal layer 114 between the first and second metallic structures 118-1 and 118-2.

The fourth etch mask 123 exposes portions of the first metal layer 114 that are etched down to the substrate 110 using a dry etch process (e.g., RIE). Following the etch process, any remaining portion of the fourth etch mask 123 is removed, which results in the exemplary quantum device 100 shown in FIGS. 1A and 1B, as discussed above. The etch process results in formation (and isolation) of the metallic interconnect structure 114-1 from the first metal layer 114, which is electrically coupled to the metallic structure 118-1. Moreover, as noted above and as shown in FIGS. 1A and 1B, at least a portion of the metallic interconnect structure 114-1 comprises the first electrode 120-1 of the superconducting tunnel junction device 120, wherein the first electrode 120-1 of the superconducting tunnel junction device 120 is electrically coupled to the first metallic structure 118-1 (e.g., capacitor electrode) via the metallic structure 114-1.

It is to be appreciated that the exemplary wafer-scale fabrication process as discussed above incorporates process modules for fabricating superconducting tunnel junction devices (e.g., Josephson junctions) as part of the process module for fabricating other superconducting components and circuitry. In this regard, the wafer-scale fabrication process eliminates the need to utilize separate junction build processes, such as double shadow evaporation techniques, to first build the junction devices, and then implement separate process modules (e.g., CMOS process modules) for wafer-scale fabrication of quantum devices. As noted above, double shadow evaporation techniques are incompatible with large-scale manufacturing, result in non-idealities of junction parameters, and have high process variability.

Advantageously, the exemplary fabrication techniques as discussed herein allow the electrodes of the superconducting tunnel junction devices to be integrally formed with superconducting pads (e.g., capacitor pads of superconducting quantum bits), which results in high-performance electrical contacts between the superconducting pads and electrodes of junction devices. In particular, as demonstrated above, the exemplary fabrication process allows the metallization (i.e., first and second metallic structures 118-1 and 118-2 (e.g., capacitor pads) and the first and second electrodes 120-1 and 120-2) to be formed on both sides of the superconducting tunnel junction device 120 via a single “deposition process module” (which comprises depositing the first metal layer 114, forming the insulating layer 116, and depositing the second metal layer 118), without breaking vacuum in a deposition chamber, and without relying on a separate double angle shadow evaporation process. It is important to maintain vacuum during the deposition process, otherwise breaking vacuum can introduce contaminants, alter film properties, and affect the overall quality of the deposited layers. The single deposition process module enables integration of the metallization features on both sides of the superconducting tunnel junction device 120, which is followed by patterning steps to further define and form, e.g., the capacitor pads and junction device electrodes.

Moreover, the undercut trench 112 naturally enables a patterning of the first metal layer 114 during deposition of the first metal layer 114 (of the “deposition process module”) by providing a discontinuity in the first metal layer 114 near the region where the superconducting tunnel junction device 120 is formed. In this regard, the undercut trench 112 enables an initial isolation/separation of the metallization that ultimately forms the first and second electrodes 120-1 and 120-2 on one side of the superconducting tunnel junction device 120.

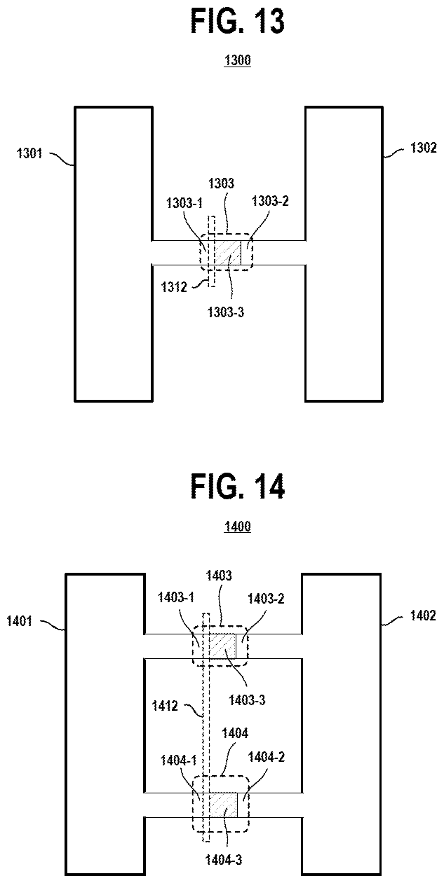

As noted above, in some embodiments, the quantum device 100 shown in FIGS. 1A and 1B comprises a superconducting qubit which comprises a superconducting capacitor coupled in parallel with a Josephson junction, wherein the first and second metallic structures 118-1 and 118-2 comprise first and second capacitor electrodes of a coplanar parallel plate capacitor, and the superconducting tunnel junction device 120 is a Josephson junction that is coupled to and between the first and second capacitor electrodes of the coplanar parallel plate capacitor. For example, FIG. 13 schematically illustrates a superconducting qubit 1300 which can be constructed using the exemplary fabrication process of FIGS. 2A-12B, as discussed above.

The superconducting qubit 1300 comprises a first superconducting pad 1301, a second superconducting pad 1302, and a Josephson junction 1303 coupled to, and disposed between, the first and second superconducting pads 1301 and 1302. The first and second superconducting pads 1301 and 1302 comprise electrodes of a coplanar parallel-plate capacitor structure of the superconducting qubit 1300. The Josephson junction 1303 functions as a non-linear inductor which, when shunted with the capacitor formed by the first and second superconducting pads 1301 and 1302, forms an anharmonic LC oscillator with individually addressable energy levels (e.g., two lowest energy levels corresponding to a ground state |0) and a first excited state |1)) with a given transition frequency f₀₁.

The Josephson junction 1303 comprises a first electrode 1303-1, a second electrode 1303-2, and a barrier layer 1303-3 disposed between overlapping portions of the first and second electrodes 1303-1 and 1303-2. In an exemplary embodiment, based on the fabrication process discussed above, the first superconducting pad 1301 and the first electrode 1303-1 are integrally and concurrently formed from the same metal deposition process. In addition, the first and second superconducting pads 1301 and 1302 are concurrently formed via the same metal deposition process. The second electrode 1303-2 is formed by a separate metal deposition process, and electrically connected to the second superconducting pad 1302. An undercut trench 1312 formed in the underlying substrate would facilitate formation of the Josephson junction 1303 as discussed above.

Next, FIG. 14 schematically illustrates a frequency-tunable superconducting quantum bit having Josephson junctions which can be constructed using a fabrication method according to an exemplary embodiment of the disclosure. More specifically, FIG. 14 schematically illustrates a frequency-tunable superconducting qubit 1400 which comprises a first superconducting pad 1401, a second superconducting pad 1402, and a first Josephson junction 1403 and second Josephson junction 1404 coupled in parallel to, and disposed between, the first and second superconducting pads 1401 and 1402. The first and second superconducting pads 1401 and 1402 comprise electrodes of a coplanar parallel-plate capacitor structure of the superconducting qubit 1400. The first and second Josephson junctions 1403 and 1404 function as a non-linear inductor which, when shunted with the capacitor formed by the first and second superconducting pads 1401 and 1402, forms an anharmonic LC oscillator with individually addressable energy levels (e.g., two lowest energy levels corresponding to a ground state |0) and a first excited state |1)) with a given transition frequency f₀₁. The first and second Josephson junctions 1403 and 1404 form a SQUID and associated superconducting loop (referred to as SQUID loop) through which an external magnetic flux ϕ can be threaded to tune the transition frequency of the frequency-tunable superconducting quantum bit 1400, as is understood by those of ordinary skill in the art.

The first Josephson junction 1403 comprises a first electrode 1403-1, a second electrode 1403-2, and a barrier layer 1403-3 disposed between overlapping portions of the first and second electrodes 1403-1 and 1403-2. Similarly, the second Josephson junction 1404 comprises a first electrode 1404-1, a second electrode 1404-2, and a barrier layer 1404-3 disposed between overlapping portions of the first and second electrodes 1404-1 and 1404-2. The first and second Josephson junction 1403 and 1404 in FIG. 14 can be constructed using a fabrication process which is similar to the exemplary fabrication process of FIGS. 2A-12B as discussed above, but wherein the etch masks would be configured to enable the patterning of the metallization layer, etc., to concurrently fabricate a pair of parallel superconducting tunnel junction devices between the first and second metallic structures 118-1 and 118-2, as opposed to just the single superconducting tunnel junction device 120.

In this regard, based on the fabrication process discussed above, in an exemplary embodiment, the first superconducting pad 1401 and the first electrodes 1403-1 and 1404-1 would be integrally and concurrently formed from the same metal deposition process, along with the second superconducting pad 1402. In addition, the second electrodes 1403-2 and 1404-2 would be concurrently formed by a separate metal deposition process, and electrically connected to the second superconducting pad 1402. Moreover, in some embodiments, as shown in FIG. 14, a single undercut trench 1412 with the appropriate length is formed in the underlying substrate to enable formation of the first and second Josephson junctions 1403 and 1404, as discussed above.

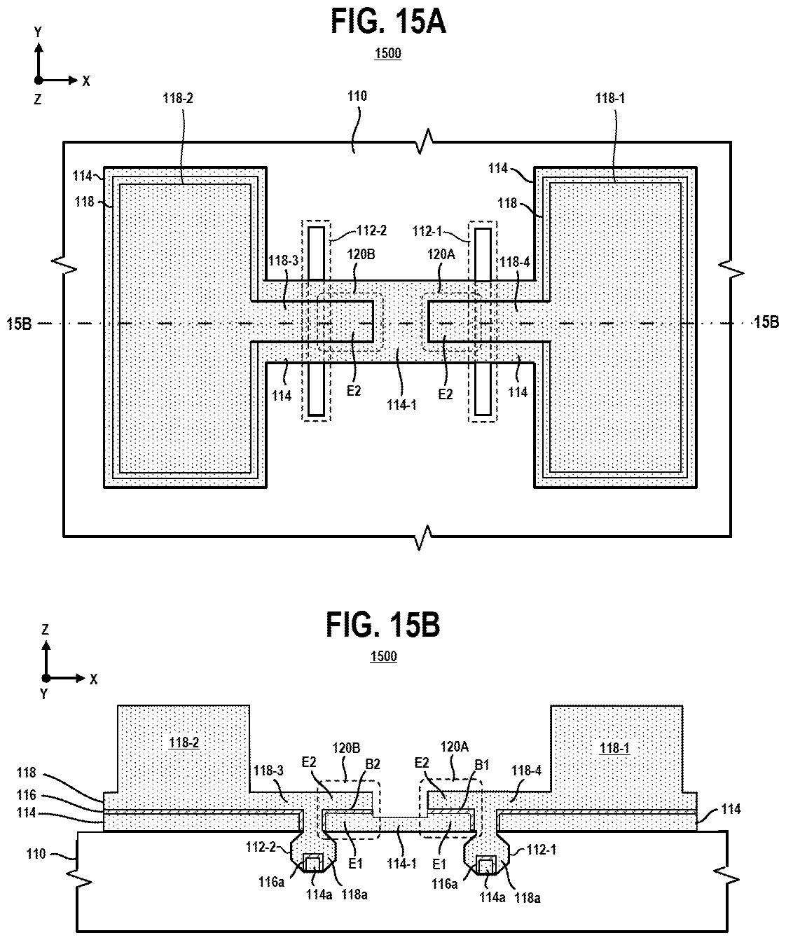

FIGS. 15A and 15B schematically illustrate a quantum device 1500 comprising serially-connected superconducting tunnel junction devices, according to another exemplary embodiment of the disclosure, wherein FIG. 15A is a schematic top plan view of the quantum device 1500, and FIG. 15B is a schematic cross-sectional side view of the quantum device 1500 along line 15B-15B in FIG. 15A. The quantum device 1500 (e.g., quantum chip) is similar to the quantum device 100 of FIGS. 1A and 1B, except that the quantum device 1500 comprises a first superconducting tunnel junction device 120A and a second superconducting tunnel junction device 120B, and utilizes a first undercut trench 112-1 and a second undercut trench 112-2 to facilitate the fabrication of the first and second superconducting tunnel junction devices 120A and 120B.

The first superconducting tunnel junction device 120A comprises a first electrode E1, a second electrode E2, and a barrier layer B1 disposed between the first and second electrodes E1 and E2 thereof. Similarly, the second superconducting tunnel junction device 120B comprises a first electrode E1, a second electrode E2, and a barrier layer B2 disposed between the first and second electrodes E1 and E2 thereof. As schematically shown in FIGS. 15A and 15B, the first and second undercut trenches 112-1 and 112-2 are configured to enable isolation of a metallic interconnect structure 114-1 after depositing and patterning the first metal layer 114. The metallic interconnect structure 114-1 comprises the first electrodes E1 of the first and second superconducting tunnel junction devices 120A and 120B. In this regard, the metallic interconnect structure 114-1 comprises a common (and isolated) connection between the first electrodes E1 of the first and second superconducting tunnel junction devices 120A and 120B.

Moreover, the insulating layer 116 is patterned to form the respective barrier layers B1 and B2 of the first and second superconducting tunnel junction devices 120A and 120B. In addition, similar to the exemplary embodiment of the quantum device 100 discussed above, the second metal layer 118 is patterned to form, e.g., the first metallic structure 118-1, the second metallic structure 118-2, and the third metallic structure 118-3, wherein at least a portion of the third metallic structure 118-3 comprises the second electrode E2 of the second superconducting tunnel junction device 120B. Further, with the exemplary quantum device 1500, second metal layer 118 is patterned to form a fourth metallic structure 118-4, wherein at least a portion of the fourth metallic structure 118-4 comprises the second electrode E2 of the first superconducting tunnel junction device 120A.

It is to be understood that the exemplary quantum device 1500 of FIGS. 15A and 15B can be fabricated using the same and/or similar techniques and process modules as discussed above in conjunction with FIGS. 2A-12B, the details of which are readily understood by those of ordinary skill in the art based on the teachings herein and, thus, need not be described in detail. In this regard, based on the fabrication process discussed above, the first metallic structure 118-1, the second metallic structure 118-2, the third metallic structure 118-3, and the fourth metallic structure 118-4 (and thus the second electrodes E2 of the first and second superconducting tunnel junction devices 120A and 120B) would be integrally formed from the same metal layer, e.g., by depositing and patterning the second metal layer 118.

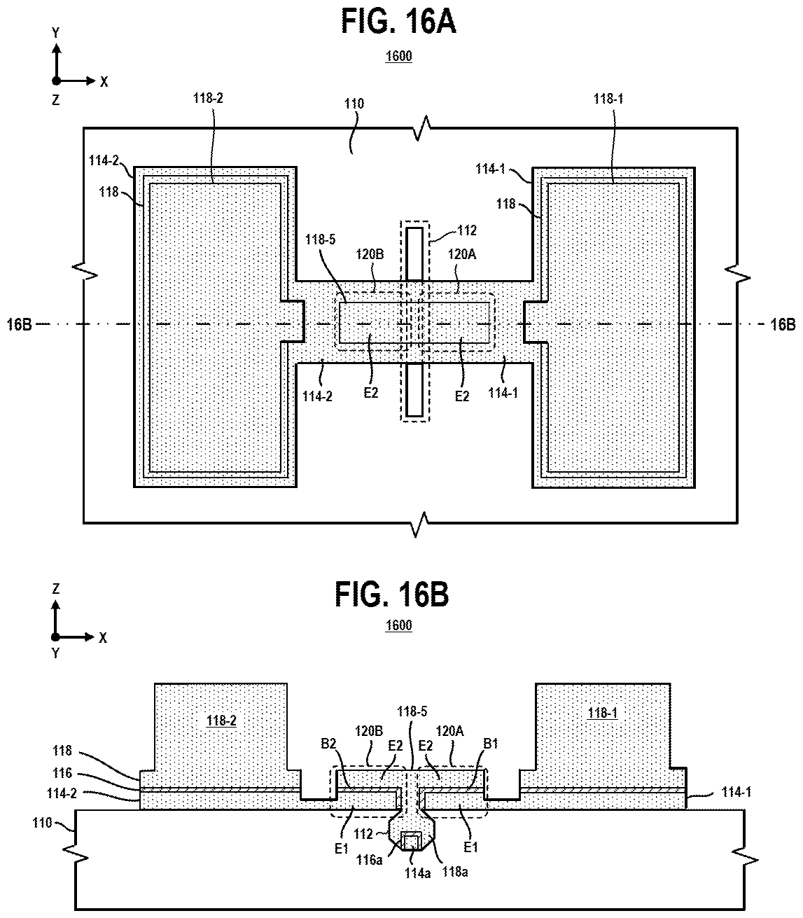

FIGS. 16A and 16B schematically illustrate a quantum device 1600 comprising serially-connected superconducting tunnel junction devices, according to another exemplary embodiment of the disclosure, wherein FIG. 16A is a schematic top plan view of the quantum device 1600, and FIG. 16B is a schematic cross-sectional side view of the quantum device 1600 along line 16B-16B in FIG. 16A. The quantum device 1600 (e.g., quantum chip) is similar to the quantum device 1500 of FIGS. 15A and 15B in that the quantum device 1600 comprises first and second superconducting tunnel junction devices 120A and 120B. However, in the exemplary embodiment of FIGS. 16A and 16B, a single undercut trench 112 is utilized to facilitate the fabrication of the first and second superconducting tunnel junction devices 120A and 120B on opposite sides of the single undercut trench 112.

In particular, the quantum device 1600 comprises first and second metallic interconnect structures 114-1 and 114-2, which are formed by patterning the first metal layer 114, and which are electrically isolated via the undercut trench 112. Moreover, the first metallic interconnect structure 114-1 is electrically connected to the first metallic structure 118-1, wherein at least a portion of the first metallic interconnect structure 114-1 comprises the first electrode E1 of the first superconducting tunnel junction device 120A. Further, the second metallic interconnect structure 114-2 is electrically connected to the second metallic structure 118-2, wherein at least a portion of the second metallic interconnect structure 114-2 comprises the first electrode E1 of the second superconducting tunnel junction device 120B.

As further shown in FIGS. 16A and 16B, a metallic structure 118-5 is patterned from the same metallic material (e.g., second metal layer 118) which forms the first and second metallic structures 118-1 and 118-2. The metallic structure 118-5 comprises the second electrodes E2 of the first and second superconducting tunnel junction devices 120A and 120B. In this regard, the metallic structure 118-5 provides a common (and isolated) connection between the second electrodes EE of the first and second superconducting tunnel junction devices 120A and 120B. The insulating layer 116 is patterned to form the respective barrier layers B1 and B2 of the first and second superconducting tunnel junction devices 120A and 120B. It is to be understood that the exemplary quantum device 1600 of FIGS. 16A and 16B can be fabricated using the same and/or similar techniques and process modules as discussed above in conjunction with FIGS. 2A-12B, the details of which are readily understood by those of ordinary skill in the art based on the teachings herein and, thus, need not be described in detail.

FIGS. 1A and 1B schematically illustrate an asymmetric configuration in which a single superconducting tunnel junction device 120 is connected between two superconducting pads in a full build, while FIGS. 15A/15B and 16A/16B schematically illustrate alternate embodiments of symmetric configurations in which two serially connected superconducting tunnel junction devices 120A and 120B are connected between two superconducting pads in a full build. It is to be noted that the exemplary quantum device 1500 of FIGS. 15A and 15B comprises a device architecture which does not include parasitic tunnel junction devices in the electrical path between the first and second metallic structures 118-1 and 118-2. Indeed, as shown in FIGS. 15A and 15B, the first and second metallic structures 118-1 and 118-2 are integrally connected to the respective metallic interconnect structures 118-4 and 118-3 and, therefore, are directly connected to the second electrodes E2 of the respective first and second superconducting tunnel junction devices 120A and 120B.

On the other hand, the exemplary quantum device 1600 of FIGS. 16A and 16B comprises a device architecture which does include two large parasitic tunnel junction devices in the electrical path between the first and second metallic structures 118-1 and 118-2. Indeed, as shown in FIGS. 16A and 16B, a first parasitic tunnel junction device is formed by the portion of the insulating layer 116 disposed between the overlapping portions of the first metallic structure 118-1 and the first metallic interconnect structure 114-1, and a second parasitic tunnel junction device is formed by the portion of the insulating layer 116 disposed between the overlapping portions of the second metallic structure 118-2 and the second metallic interconnect structure 114-2. In this configuration, the first and second superconducting tunnel junction devices 120A and 120B are serially connected with the two large parasitic tunnel junction devices between the between the first and second metallic structures 118-1 and 118-2. However, for the same reasons discussed above, given the relatively large sizes (areas) of the two parasitic tunnel junction devices as compared to the much smaller sizes (areas) of the first and second superconducting tunnel junction devices 120A and 120B, the presence of the two large parasitic tunnel junction devices does not adversely impact device performance.

In an alternate embodiment of the quantum device 1600 of FIGS. 16A and 16B, direct contact can be made to the first and second metallic interconnect structures 114-1 and 114-2 by (i) forming through vias in the substrate 110, which are coupled to the first and second metallic interconnect structures 114-1 and 114-2, and (ii) forming backside contacts/pads on an opposite (bottom) side of the substrate 110, which are directly connected to the first and second metallic interconnect structures 114-1 and 114-2 by the through vias. This exemplary configuration would eliminate the presence of parasitic junctions in the electrical path between the two backside contacts with only the two superconducting tunnel junction devices 120A and 120B in the current path between the two backside contacts.

In alternative embodiments, the exemplary asymmetric and symmetric configurations can be implemented in an “junction-first build” where the superconducting tunnel junction devices are fabricated first, followed by fabrication of other elements (e.g., superconducting capacitor pads, inductors, resonators, interconnects, etc.) by separate metal deposition and patterning process. This separate “junction-first build” process can be implemented in instances where the electrode of the junction devices are to be formed with superconducting metal which is different from the superconducting metals to form other devices, while still enabling the use of wafer-scale fabrication techniques to construct the junction devices without having to utilize double shadow evaporation techniques which, as noted above, are incompatible with large scale manufacturing, result in non-idealities and have high process variability.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A method, comprising:
forming an undercut trench in a surface of a substrate;
forming a first superconducting metal layer on the surface of the substrate such that the undercut trench causes a discontinuity in the first superconducting metal layer;
forming an insulating layer on the first superconducting metal layer;
forming a second superconducting metal layer on the insulating layer; and
patterning the second superconducting metal layer, the insulating layer, and the first superconducting metal layer to form at least one superconducting tunnel junction device in an area of the substrate adjacent to the undercut trench;
wherein the at least one superconducting tunnel junction device comprises a first electrode, a second electrode, and a barrier layer disposed between the first electrode and the second electrode, the first electrode comprising a portion of the first superconducting metal layer at the discontinuity thereof, the barrier layer comprising a portion of the insulating layer, and the second electrode comprising a portion of the second superconducting metal layer.

2. The method of claim 1, wherein forming the second superconducting metal layer comprises depositing a superconducting metallic material which fills the discontinuity in the first superconducting metal layer.

3. The method of claim 2, wherein a portion of the second electrode of the at least one superconducting tunnel junction device comprises the superconducting metallic material which fills the discontinuity in the first superconducting metal layer.

4. The method of claim 1, wherein the first superconducting metal layer and the second superconducting metal layer each comprise aluminum.

5. The method of claim 1, wherein forming the insulating layer on the first superconducting metal layer comprises oxidizing a surface of the first superconducting metal layer to form an oxide layer.

6. The method of claim 1, wherein the first superconducting metal layer, the insulating layer, and the second superconducting metal layer are formed using a single deposition process module that is performed without breaking a vacuum in a deposition chamber.

7. The method of claim 1, wherein the at least one superconducting tunnel junction device comprises a Josephson junction of a superconducting quantum bit.

8. The method of claim 1, wherein patterning the second superconducting metal layer, the insulating layer, and the first superconducting metal layer to form at least one superconducting tunnel junction device in an area of the substrate adjacent to the undercut trench, comprises patterning the second superconducting metal layer, the insulating layer, and the first superconducting metal layer to form a first superconducting tunnel junction device and a second superconducting tunnel junction device adjacent to and on opposite sides of the undercut trench, wherein the first and second superconducting tunnel junction devices are serially connected.

9. A method, comprising:
forming an undercut trench in a surface of a substrate;
forming a first superconducting metal layer on the surface of the substrate such that the undercut trench causes a discontinuity in the first superconducting metal layer;
forming an insulating layer on the first superconducting metal layer;
forming a second superconducting metal layer on the insulating layer; and
patterning the second superconducting metal layer, the insulating layer, and the first superconducting metal layer to form a superconducting quantum bit;
wherein the superconducting quantum bit comprises a first capacitor pad, a second capacitor pad, and at least one Josephson junction disposed between and connected to the first capacitor pad and the second capacitor pad, and
wherein the at least one Josephson junction comprises a first electrode, a second electrode, and a barrier layer disposed between the first electrode and the second electrode, the first electrode comprising a portion of the first superconducting metal layer at the discontinuity thereof, the barrier layer comprising a portion of the insulating layer, and the second electrode comprising a portion of the second superconducting metal layer.

10. The method of claim 9, wherein forming the second superconducting metal layer comprises depositing a superconducting metallic material which fills the discontinuity in the first superconducting metal layer.

11. The method of claim 10, wherein a portion of the second electrode of the at least one Josephson junction comprises the superconducting metallic material which fills the discontinuity in the first superconducting metal layer.

12. The method of claim 9, wherein the first superconducting metal layer and the second superconducting metal layer each comprise aluminum.

13. The method of claim 9, wherein forming the insulating layer on the first superconducting metal layer comprises oxidizing a surface of the first superconducting metal layer to form an oxide layer.

14. The method of claim 9, wherein the first superconducting metal layer, the insulating layer, and the second superconducting metal layer are formed using a single deposition process module that is performed without breaking a vacuum in a deposition chamber.

15. The method of claim 9, wherein patterning the second superconducting metal layer, the insulating layer, and the first superconducting metal layer to form at least one Josephson junction, comprises patterning the second superconducting metal layer, the insulating layer, and the first superconducting metal layer to form a first Josephson junction and a second Josephson junction adjacent to and on opposite sides of the undercut trench, wherein the first and second Josephson junctions are serially connected.

16. A device, comprising:
a substrate comprising at least one undercut trench formed in a surface thereof;
at least one superconducting tunnel junction device disposed on the substrate adjacent to an opening of the undercut trench, the at least one superconducting tunnel junction device comprising a first electrode, a second electrode, and a barrier layer disposed between the first electrode and the second electrode;
wherein the first electrode is disposed adjacent to the opening of the undercut trench, and
wherein a first portion of the second electrode is disposed over an upper surface of the first electrode, and a second portion of the second electrode is disposed adjacent to a sidewall surface of the first electrode and extends to the opening of the undercut trench.

17. The device of claim 16, wherein the at least one superconducting tunnel junction device comprises a Josephson junction of a superconducting quantum bit.

18. The device of claim 17, further comprising:
a first capacitor pad and a second capacitor pad disposed on the substrate;
wherein the Josephson junction is connected to and between the first capacitor pad and the second capacitor pad; and
wherein the first capacitor pad, the second capacitor pad, and the second electrode are patterned from a same superconducting metal layer.

19. The device of claim 18, wherein the at least one superconducting tunnel junction device disposed on the substrate adjacent to the opening of the undercut trench comprises a first superconducting tunnel junction device and a second superconducting tunnel junction device disposed adjacent to and on opposite sides of the undercut trench, wherein the first and second superconducting tunnel junction devices are serially connected.

20. The device of claim 16, wherein:
the at least one undercut trench comprises a first undercut trench and a second undercut trench formed in the surface of the substrate;
the at least one superconducting tunnel junction device comprises a first superconducting tunnel junction device disposed on the substrate adjacent to an opening of the first undercut trench, and a second superconducting tunnel junction device disposed on the substrate adjacent to an opening of the second undercut trench; and
the first electrode of the at least one superconducting tunnel junction device comprises a common first electrode of the first and second superconducting tunnel junction devices.
